(19) United States
(12) Patent Application Publication
(10) Pub. No.: US 2024/0234554 A1
(43) Pub. Date: Jul. 11, 2024

(54) SEMICONDUCTOR DEVICE

(71) Applicant: FUJI ELECTRIC CO., LTD., Kanagawa (JP)

(72) Inventor: Naoki MITAMURA, Matsumoto-city (JP)

(21) Appl. No.: 18/515,275

(22) Filed: Nov. 21, 2023

(30) Foreign Application Priority Data
Jan. 10, 2023 (JP) 2023-002015

(51) Int. Cl. H01L 29/739; H01L 27/07; H01L 29/06; H01L 29/08; H01L 29/861

(52) U.S. Cl. CPC H01L 29/7397; H01L 27/0727; H01L 29/0696; H01L 29/0834; H01L 29/861

(57) ABSTRACT

Provided is a semiconductor device including a transistor portion and a diode portion, where the semiconductor device including: a plurality of trench portions provided on a front surface of a semiconductor substrate; a drift region of a first conductivity type provided in the semiconductor substrate; an anode region of a second conductivity type provided above the drift region in the diode portion; a low concentration region provided above the anode region and having a doping concentration an absolute value of which is lower than that of the anode region; and a high concentration region of the second conductivity type provided above the anode region and having a doping concentration higher than that of the anode region.

### BACKGROUND

### 1. Technical Field

The present invention relates to a semiconductor device.

### 2. Related Art

Patent Literature 1 discloses providing an anode layer of p-type on the surface of the semiconductor device to control the implantation efficiency from the anode side, thereby adjusting the trade off characteristics between the ON voltage and the recovery loss.

### PRIOR ART LITERATURE

### Patent Literature

Patent Literature 1: Japanese Patent Application Publication No. 2018-152443

### BRIEF DESCRIPTION OF THE DRAWINGS

FIG. 1A shows an example of a top view of a semiconductor device 100 according to the example.

FIG. 1B is a diagram showing an example of the cross section a-a′ in FIG. 1A.

FIG. 2A shows an example of a top view of the semiconductor device 1100 according to the comparative example.

FIG. 2B is a diagram showing an example of a cross section a-a′ in FIG. 2A.

FIG. 3 is a diagram showing the doping concentration profiles in the mesa portions 81 of the example and the comparative example.

FIG. 4 is a diagram schematically showing paths of hole currents while the diode portions 80 of the example and the comparative example are brought into conduction.

FIG. 5A shows another example of a top view of the semiconductor device 100.

FIG. 5B is a diagram showing an example of a cross section a-a′ in FIG. 5A.

FIG. 6A is a diagram showing another example of a cross section a-a′ in FIG. 1A.

FIG. 6B is a diagram showing another example of a cross section a-a′ in FIG. 1A.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer, or other member is referred to as a front surface, and the other surface is referred to as a back surface. “Upper”, “lower”, “front”, and “back” directions are not limited to a direction of gravity, or a direction of an attachment to a substrate or the like when a semiconductor device is mounted.

In the present specification, technical matters may be described with orthogonal coordinate axes consisting of an X axis, a Y axis, and a Z axis. In the present specification, a plane parallel to a front surface of the semiconductor substrate is referred to as an X-Y plane, and a depth direction of the semiconductor substrate is referred to as the Z axis. It should be noted that in the present specification, a case where the semiconductor substrate is viewed in a Z axis direction is referred to as a top view.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. In addition, each of a symbol “+” and a symbol “−” added to N or P represents a layer or a region of a higher doping concentration and a lower doping concentration than that of a layer or a region without the symbol, and a symbol “++” represents a higher doping concentration than “+” while a symbol “−−” represents a lower doping concentration than “−”.

In the present specification, a doping concentration refers to a concentration of a donor or a dopant that has turned into an acceptor. Accordingly, a unit thereof is/cm³. In the present specification, a difference in concentration (that is, a net doping concentration) between the donor and the acceptor may be set as the doping concentration. In this case, the doping concentration can be measured by an SRP method. In addition, a chemical concentration of the donor and the acceptor may also be set as the doping concentration. In this case, the doping concentration can be measured by an SIMS method. If not particularly limited, any of the above may be used as the doping concentration. If not particularly limited, a peak value of a doping concentration distribution in a doping region may be set as the doping concentration in the doping region.

In addition, as used herein, a dose amount refers to the number of ions implanted in a wafer per unit area when ions are implanted. Accordingly, a unit thereof is/cm². It should be noted that a dose amount of a semiconductor region can be set as an integrated concentration obtained by integrating doping concentrations over the depth direction of the semiconductor region. A unit of the integrated concentration is/cm². Accordingly, the dose amount and the integrated concentration may be treated as the same. The integrated concentration may also be an integral value up to a half-value width, and in a case of being overlapped by a spectrum of another semiconductor region, the integrated concentration may be derived without an influence of the other semiconductor region.

Therefore, in the present specification, a level of the doping concentration can be read as a level of the dose amount. That is, when the doping concentration of one region is higher than the doping concentration of another region, it can be understood that the dose amount of the one region is higher than the dose amount of the other region.

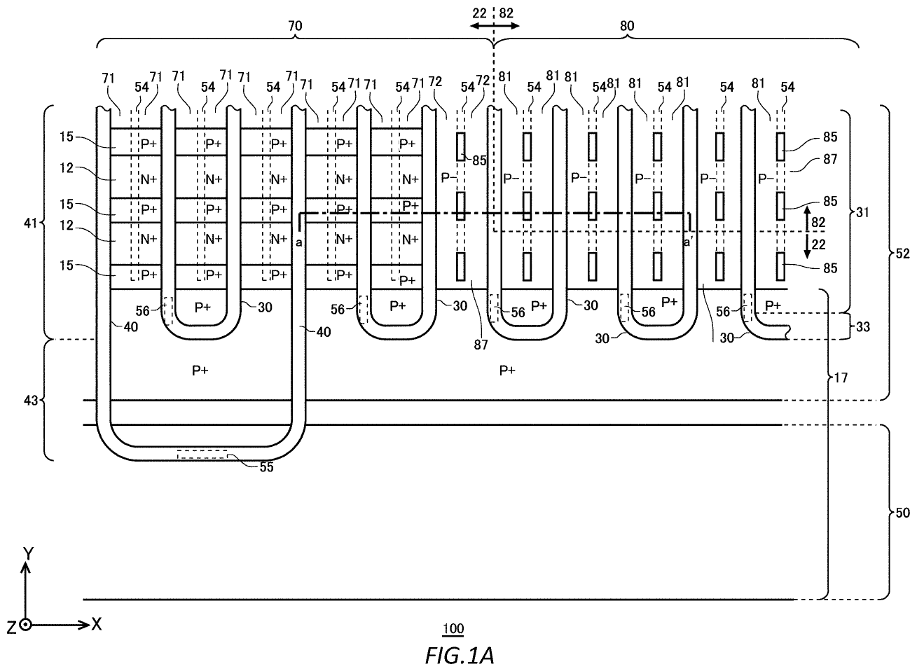

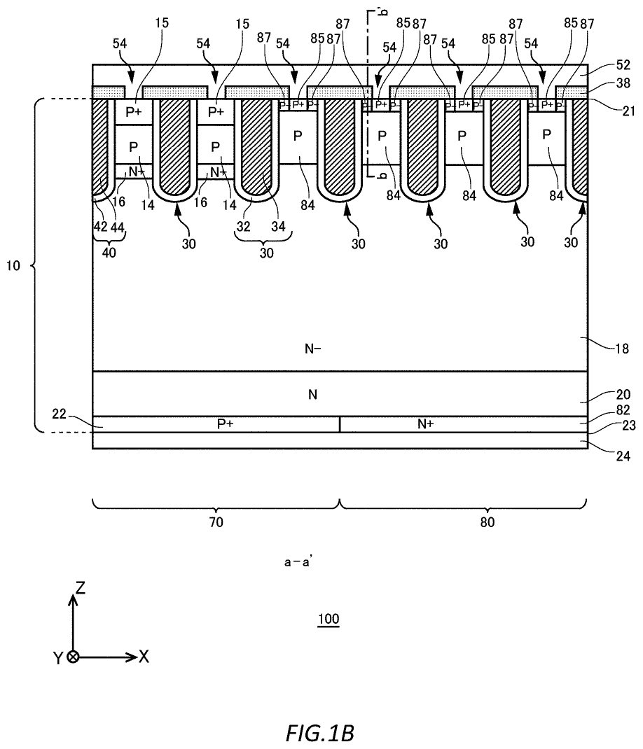

FIG. 1A shows an example of a top view of a semiconductor device 100 according to the example. The semiconductor device 100 is provided with the semiconductor substrate having the transistor portion 70 including a transistor element such as an IGBT and the diode portion 80 including a diode element such as a free wheel diode (FWD). For example, the semiconductor device 100 is a reverse conducting IGBT (RC-IGBT).

Note that, in the present specification, when simply referred to as a top view, it means viewing from the front surface side of the semiconductor substrate. In the present example, an arrangement direction of the transistor portion 70 and the diode portion 80 in a top view is referred to as an X axis, a direction perpendicular to the X axis on the front surface of the semiconductor substrate is referred to as a Y axis, and a direction perpendicular to the front surface of the semiconductor substrate is referred to as a Z axis.

Each of the transistor portion 70 and the diode portion 80 may have a longitudinal length in an extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

The transistor portion 70 is a region where a collector region 22 provided on a back surface side of the semiconductor substrate is projected onto a front surface of a semiconductor substrate. The collector region 22 of the present example is, for example, of the P type. The transistor portion 70 includes a transistor such as an IGBT.

In the transistor portion 70, an N type emitter region 12, a P type base region 14, and a gate trench portion 40 including a gate conductive portion and a gate dielectric film are arranged at regular intervals on the front surface side of the semiconductor substrate. As used herein, the front surface side of the semiconductor substrate may mean the side of the front surface compared to the center of the semiconductor substrate in the Z axis direction.

The diode portion 80 is a region where a cathode region 82 provided on the back surface side of the semiconductor substrate is projected onto the front surface of the semiconductor substrate. The cathode region 82 of the present example is, for example, of the N type. The diode portion 80 includes a diode such as a free wheel diode (FWD: Free Wheel Diode) provided to be adjacent to the transistor portion 70 on the front surface of the semiconductor substrate. On the back surface of the semiconductor substrate, a collector region of the P type may be provided in a region other than the cathode region.

The semiconductor substrate may be a silicon substrate, a silicon carbide substrate, or a nitride semiconductor substrate and so forth of gallium nitride or the like. The semiconductor substrate of the present example is a silicon substrate.

The semiconductor device 100 of the present example includes a gate trench portion 40, a dummy trench portion 30, an emitter region 12, a contact region 15, a well region 17, a high concentration region 85, and a low concentration region 87, provided in the front surface side of the semiconductor substrate. The gate trench portion 40 and the dummy trench portion 30 each are an example of the trench portion.

In addition, the semiconductor device 100 in the present example includes a gate metal layer 50 and an emitter electrode 52 which are provided above the front surface of the semiconductor substrate. An interlayer dielectric film is provided between the emitter electrode 52 and the gate metal layer 50, and the front surface of the semiconductor substrate, but it is omitted in FIG. 1A. In the interlayer dielectric film of the present example, contact holes 54, 55, and 56 are provided to extend through the interlayer dielectric film. In FIG. 1A, each of the contact holes is indicated by a dashed line.

The emitter electrode 52 is provided above the gate trench portion 40, the dummy trench portion 30, the emitter region 12, the contact region 15, the well region 17, the high concentration region 85, and the low concentration region 87. The emitter electrode 52 is electrically connected to the emitter region 12, the contact region 15, the high concentration region 85, and the low concentration region 87 on the front surface of the semiconductor substrate through the contact hole 54.

The emitter electrode 52 and the gate metal layer 50 are formed of a material including metal. At least a part of a region of the emitter electrode 52 may be formed of aluminum, or alloy of which main component is aluminum (for example, aluminum-silicon alloy, aluminum-silicon-copper alloy, or the like). At least a partial region of the gate metal layer 50 may be formed of aluminum, or an alloy a main component of which is aluminum (for example, an aluminum-silicon alloy, an aluminum-silicon-copper alloy, or the like).

The emitter electrode 52 and the gate metal layer 50 may include a barrier metal formed of titanium, titanium compound, or the like under the region formed of aluminum and the like. The emitter electrode 52 and the gate metal layer 50 are provided separately from each other.

The contact hole 55 connects a gate conductive portion within the gate trench portion 40 in the transistor portion 70 and the gate metal layer 50. In the contact hole 55, a plug formed of tungsten or the like may be provided through a barrier metal.

The contact hole 56 connects a dummy conductive portion in the dummy trench portion 30 provided in the transistor portion 70 and the diode portion 80 to the emitter electrode 52. In the contact hole 56, a plug formed of tungsten or the like may be provided through a barrier metal.

The gate trench portion 40 is arranged at a predetermined interval along a predetermined arrangement direction (the X axis direction in the present example). The gate trench portion 40 of the present example may have: two extending portions 41 that extend along an extending direction (the Y axis direction in the present example) which is parallel to the front surface of the semiconductor substrate and which is perpendicular to the arrangement direction; and a connecting portion 43 that connects the two extending portions 41.

Preferably, at least a part of the connecting portion 43 is formed in a curved shape. By connecting end portions of the two extending portions 41 of the gate trench portion 40, an electric field strength at the end portions of the extending portions 41 can be reduced. At the connecting portion 43 of the gate trench portion 40, the gate metal layer 50 may be connected to the gate conductive portion.

The dummy trench portion 30 is a trench portion in which the dummy conductive portion is provided to be electrically connected to the emitter electrode 52. Similar to the gate trench portions 40, the dummy trench portions 30 are arranged at predetermined intervals along a predetermined arrangement direction (the X axis direction in the present example). Similar to the gate trench portion 40, the dummy trench portion 30 of the present example may be in a U shape on the front surface of the semiconductor substrate. That is, the dummy trench portion 30 may include two extending portions 31 extending along the Y axis direction and a connecting portion 33 connecting the two extending portions 31.

The transistor portion 70 of the present example has a structure in which one gate trench portion 40 and two dummy trench portions 30 are repeatedly arranged. In other words, the transistor portion 70 of the present example has the gate trench portions 40 and the dummy trench portions 30 at a ratio of 1:2. For example, in the transistor portion 70, two extending portions 31 are arranged between two extending portions 41 adjacent to each other in the arrangement direction.

The ratio of the gate trench portions 40 and the dummy trench portions 30 is not limited to that of the present example. The ratio of the gate trench portions 40 and the dummy trench portions 30 may be 1:1, or may also be 2:3. Alternatively, the transistor portion 70 in the present example may have a so-called full-gate structure in which the dummy trench portion 30 is not provided but only the gate trench portions 40 are provided in the transistor portion 70.

The well region 17 is provided to be closer to the front surface side of the semiconductor substrate than the drift region 18 which will be described below. The well region 17 is an example of a well region provided on an edge side of the semiconductor device 100. The well region 17 is of the P+ type as an example. The well region 17 is provided within a predetermined range from an end of an active region on a side where the gate metal layer 50 is provided.

A diffusion depth of the well region 17 may be deeper than depths of the gate trench portion 40 and the dummy trench portion 30. Parts of regions of the gate trench portion 40 and the dummy trench portion 30 on a gate metal layer 50 side are provided in the well region 17. The bottoms of ends of the gate trench portions 40 and the dummy trench portions 30 in the Y axis direction may be covered by the well region 17.

The contact hole 54 is provided above each region of the emitter region 12 and the contact region 15 in the transistor portion 70. The contact hole 54 is also provided above the high concentration region 85 and the low concentration region 87 in the diode portion 80. No contact holes 54 are provided above the well regions 17 provided at the both ends in the Y axis direction. In this way, the interlayer dielectric film is provided with one or more contact holes 54. The contact hole 54 of the present example may be provided to extend in the Y axis direction.

A mesa portion 71 and a mesa portion 81 are mesa portions provided to be adjacent to the trench portion in a plane parallel to the front surface of the semiconductor substrate. The mesa portion may be a portion of the semiconductor substrate, which is sandwiched by two adjacent trench portions, and may range from the front surface of the semiconductor substrate to a depth at the lowermost bottom of each trench portion. The extending portions of each trench portion may be set to be one trench portion. That is, the region sandwiched between two extending portions may be set to be a mesa portion.

The mesa portion 71 is provided adjacent to at least one of the dummy trench portion 30 or the gate trench portion 40 in the transistor portion 70. The mesa portion 71 includes the well region 17, the emitter region 12, and the contact region 15 on the front surface of the semiconductor substrate.

The emitter region 12 is a region which is of the same conductivity type as that of the drift region 18, and which has a doping concentration higher than that of the drift region 18. The emitter region 12 in the present example is of the N+ type as an example. An example of a dopant of the emitter region 12 includes arsenic (As). The emitter region 12 is provided to be in contact with the gate trench portion 40 at a front surface of the mesa portion 71. The emitter region 12 may be provided to extend in the X axis direction from one of two trench portions sandwiching the mesa portion 71 to the other one of the two trench portions.

In addition, the emitter region 12 may or may not be in contact with the dummy trench portion 30. The emitter region 12 of the present example is in contact with the dummy trench portion 30. The emitter region 12 is not provided in the mesa portions 81.

The contact region 15 is a region of a conductivity type different from that of the drift region 18 provided on the front surface of the semiconductor substrate in the transistor portion 70. The contact region 15 in the present example is of the P+ type as an example. The contact region 15 of the present example is provided on the front surface of the mesa portion 71. The contact region 15 is provided to extend in the X axis direction from one trench portion to the other trench portion of two trench portions between which the mesa portion 71 is interposed. The transistor portion 70 of the present example includes the emitter regions 12 and the contact regions 15 on the front surface of the mesa portion 71 alternately provided in the Y axis direction. The contact region 15 is not provided in the mesa portion 81.

The transistor portion 70 may include a boundary region 72 at an end of the diode portion 80 side in a top view. The boundary region 72 is a region to prevent carriers from sneaking from the transistor portion 70 to the diode portion 80 during reverse recovery of the diode portion 80. For example, the boundary region 72 includes the high concentration region 85 and the low concentration region 87.

The high concentration region 85 is a region of a conductivity type different from that of the drift region 18 provided on the front surface of the semiconductor substrate. The high concentration region 85 of the present example is, for example, of the P+ type. The low concentration region 87 is a region provided to surround the high concentration region 85 on the front surface of the semiconductor substrate, in a top view. The low concentration region 87 of the present example is, for example, of the P-type. The high concentration regions 85 are discretely provided in the Y axis direction. In addition, the high concentration regions 85 are provided to be spaced apart from the dummy trench portion 30. That is, the high concentration regions 85 of the present example are provided in a dotted pattern in a top view. The mesa portion 71 of the boundary region 72 may also include the contact region 15 provided to extend in the Y axis direction, instead of the high concentration region 85 and the low concentration region 87.

The mesa portion 81 is provided to be adjacent to the dummy trench portion 30 in the diode portion 80. The mesa portion 81 includes the well region 17, the high concentration region 85, and the low concentration region 87 on the front surface of the semiconductor substrate.

The high concentration region 85 is a region of a conductivity type different from that of the drift region 18 provided on the front surface of the semiconductor substrate in the diode portion 80. The high concentration region 85 of the present example is, for example, of the P+type. The doping concentration of the high concentration region 85 of the present example is equal to or greater than 2E19 cm⁻³ and equal to or smaller than 2E20 cm⁻³. Note that, the E means the power of 10, and for example, 1E16 cm⁻³ means 1×10 cm⁻³. The doping concentration of the high concentration region 85 of the present example is higher than the doping concentration of the contact region 15. Alternatively, the doping concentration of the high concentration region 85 may be the same as the doping concentration of the contact region 15. In this case, the high concentration region 85 and the contact region 15 may be formed in the same process.

The high concentration regions 85 of the present example are discretely provided in the Y axis direction. In addition, the high concentration region 85 is provided to be spaced apart from the dummy trench portion 30. That is, the high concentration regions 85 of the present example are provided in a dotted pattern in the diode portion 80 in a top view.

The low concentration region 87 is a region provided to surround the high concentration region 85 on the front surface of the semiconductor substrate in the diode portion 80, in a top view. The low concentration region 87 of the present example is, for example, of the P-type. The doping concentration of the low concentration region 87 on the front surface of the semiconductor substrate is equal to or greater than 1E15 cm⁻³ and equal to or smaller than 3E16 cm⁻³. In this manner, the high concentration region 85 and the low concentration region 87 are provided such that the total amount of holes in the diode portion 80 can be reduced to suppress injection of holes and suppress the reverse recovery loss.

FIG. 1B is a diagram showing an example of the cross section a-a′ in FIG. 1A. The cross section a-a′ is an X-Z plane passing through the contact region 15 and the high concentration region 85.

The semiconductor device 100 in the present example has a semiconductor substrate 10, an interlayer dielectric film 38, the emitter electrode 52, and a collector electrode 24. The emitter electrode 52 is provided above the semiconductor substrate 10 and the interlayer dielectric film 38.

The base region 14 is a region of a conductivity type different from that of the drift region 18 provided above the drift region 18 in the mesa portion 71. The base region 14 of the present example is, for example, of the P type. The emitter region 12 and the contact region 15 are provided above the base region 14 on the front surface of the mesa portion 71. The base region 14 is provided to be in contact with the gate trench portion 40. The base region 14 may be provided to be in contact with the dummy trench portion 30.

The emitter region 12 is provided between the base region 14 and the front surface 21 of the semiconductor substrate 10. The emitter region 12 of the present example is provided in the mesa portion 71, and not provided in the mesa portions 81. The emitter region 12 is provided to be in contact with the gate trench portion 40. The emitter region 12 may or may not be in contact with the dummy trench portion 30.

The contact region 15 is provided between the base region 14 and the front surface 21 of the semiconductor substrate 10. The contact region 15 of the present example is provided in the mesa portion 71, and not provided in the mesa portions 81. The contact regions 15 of the present example are provided, in a top view, alternately with the emitter regions 12 in the Y axis direction in the mesa portion 71. The contact region 15 is provided to be in contact with the gate trench portion 40 and the dummy trench portion 30.

The anode region 84 is a region of a conductivity type different from that of the drift region 18 provided above the drift region 18 in the boundary region 72 and the mesa portion 81. The anode region 84 of the present example is, for example, of the P-type. The high concentration region 85 and the low concentration region 87 are provided above the anode region 84 on the front surfaces of the boundary region 72 and the mesa portion 81.

The thickness of the anode region 84 in the depth direction (Z axis direction) of the semiconductor substrate 10 is equal to or greater than 0.5 μm and equal to or smaller than 2.0 μm. In the Z axis direction, a peak position of the doping concentration of the anode region 84 is equal to or greater than 0.3 μm and equal to or smaller than 0.8 μm, and preferably, within the range of 0.4 to 0.6 μm, for example, 0.5 μm from the front surface 21 of the semiconductor substrate 10. The anode region 84 is provided to be in contact with the dummy trench portion 30.

The peak of the doping concentration of the anode region 84 of the present example is equal to or greater than 4E16 cm⁻³ and equal to or smaller than 1E17 cm⁻³. The doping concentration of the anode region 84 in the present example is lower than a doping concentration of the base region 14. In the present example, the doping concentration of the anode region 84 is lowered such that injection of holes can be suppressed to suppress the reverse recovery loss.

The high concentration region 85 is provided between the anode region 84 and the front surface 21 of the semiconductor substrate 10. The high concentration regions 85 of the present example are discretely provided in the Y axis direction in the boundary region 72 and the mesa portion 81. The high concentration region 85 is provided to be spaced apart from the dummy trench portion 30 in the mesa portion 81. The thickness of the high concentration region 85 in the Z axis direction is equal to or greater than 0.1 μm and equal to or smaller than 1.0 μm.

The high concentration region 85 of the present example is, for example, of the P+ type. The doping concentration of the high concentration region 85 of the present example is equal to or greater than 2E19 cm⁻³ and equal to or smaller than 2E20 cm⁻³. The doping concentration of the high concentration region 85 of the present example is higher than the doping concentration of the anode region 84. The doping concentration of the high concentration region 85 of the present example is equal to or greater than 200 times and equal to or smaller than 2000 times the doping concentration of the anode region 84.

The doping concentration of the high concentration region 85 of the present example is higher than the doping concentration of the contact region 15. Alternatively, the doping concentration of the high concentration region 85 may be the same as the doping concentration of the contact region 15. In this case, the high concentration region 85 and the contact region 15 may be formed in the same process.

The low concentration region 87 is provided between the anode region 84 and the front surface 21 of the semiconductor substrate 10. The low concentration region 87 of the present example is provided to surround the high concentration region 85 on the front surface of the mesa portion 81 in a top view. That is, the front surfaces of the boundary region 72 and the mesa portion 81 of the present example are provided with the high concentration region 85 and the low concentration region 87 such that the anode region 84 is not exposed to the front surface 21 of the semiconductor substrate 10.

An absolute value of the doping concentration of the low concentration region 87 of the present example is lower than an absolute value of the doping concentration of the anode region 84. A lower absolute value of the doping concentration means a lower doping concentration, irrespective of whether dopants are donors or acceptors. That is, the low concentration region 87 is a region having a concentration of donors or acceptors lower than a concentration of acceptors in the anode region 84. The low concentration region 87 of the present example is, for example, of the P-type.

The doping concentration of the low concentration region 87 on the front surface 21 of the semiconductor substrate 10 is equal to or greater than 1E15 cm⁻³ and equal to or smaller than 3E16 cm⁻³. The doping concentration of the low concentration region 87 is equal to or greater than 10% and equal to or smaller than 50% of the peak of the doping concentration of the anode region 84. In this manner, the high concentration region 85 and the low concentration region 87 are provided such that the total amount of holes in the diode portion 80 can be reduced to suppress injection of holes and suppress the reverse recovery loss.

When the diode portion 80 is brought into conduction, electron current flows from the cathode region 82 to the anode region 84. When the electron current reaches the anode region 84, conductivity modulation occurs and hole current flows from the anode region 84. In addition, electron currents diffusing from the cathode region 82 facilitates the hole injection from the contact region 15 of the transistor portion 70, thereby increasing the density of holes in the semiconductor substrate 10. As a result, increased time required for the hole to disappear when the diode portion 80 is turned off increases reverse recovery peak current and increases reverse recovery loss.

A technique for preventing such hole current is known, in which a lifetime control region including lifetime killers is provided on the front surface side of the semiconductor substrate. For example, the lifetime killers are electron lines implanted to the entire semiconductor substrate or helium, an electron line, or proton etc. implanted to a predetermined depth thereof. The lifetime control region is crystal defect formed in the semiconductor substrate by implanting the lifetime killers. The lifetime control region facilitates electrons and holes, which are generated when a diode portion is brought into conduction, to be eliminated in recombination, and thus reduces reverse recovery losses.

In the present example, the mesa portion 81 includes: the high concentration region 85 having a higher doping concentration and discretely provided therein; and the low concentration region 87 having a doping concentration lower than that of the anode region 84 and provided above the anode region 84, such that injection of holes can be suppressed to suppress the reverse recovery loss even if the lifetime control region is not provided.

The contact hole 54 is provided to extend through the interlayer dielectric film 38 in the depth direction (Z axis direction) of the semiconductor substrate 10 and electrically connects the emitter electrode 52 with the semiconductor substrate 10. The barrier metal formed of titanium, a titanium compound, or the like may be provided in the contact hole 54. The plug formed of tungsten or the like may be further provided through the barrier metal, in the contact hole 54.

The high concentration region 85 is provided below the contact hole 54. For example, the high concentration region 85 is formed by ion implantation of dopants such as boron (B) from the lower end of the contact hole 54. In the X axis direction, the width of the high concentration region 85 may be equal to or greater than the width of the lower end of the contact hole 54.

The accumulation region 16 is a region provided below the base region 14. The accumulation region 16 of the present example is of the same conductivity type as that of the drift region 18, and is of N+ type, as an example. The accumulation region 16 of the present example is not provided in the boundary region 72 and the diode portion 80. In the Z axis direction, two or more stages of the accumulation regions 16 may also be provided. In addition, the accumulation region 16 may also be provided in the boundary region 72 and the diode portion 80.

In addition, the accumulation region 16 is provided to be in contact with the gate trench portion 40. The accumulation region 16 may or may not be in contact with the dummy trench portion 30. The doping concentration of the accumulation region 16 is higher than the doping concentration of the drift region 18. By providing the accumulation region 16, the carrier injection enhancement effect (IE effect) can be increased, and an ON voltage of the transistor portion 70 can be reduced.

The drift region 18 is a region provided in the semiconductor substrate 10. The drift region 18 in the present example is of the N-type as an example. The drift region 18 may be a region that has remained without other doping regions being formed in the semiconductor substrate 10. That is, the doping concentration of the drift region 18 may be a doping concentration of the semiconductor substrate 10.

The buffer region 20 is a region provided below the drift region 18. The buffer region 20 of the present example may be of the same conductivity type as that of the drift region 18, and is of the N type as an example. The doping concentration of the buffer region 20 is higher than the doping concentration of the drift region 18. The buffer region 20 may function as a field stop layer to prevent a depletion layer expanded from the lower surface side of the base region 14 and the anode region 84 from reaching the collector region 22 and the cathode region 82.

The collector region 22 is a region which is provided below the buffer region 20 in the transistor portion 70 and which is of a conductivity type different from that of the drift region 18. The cathode region 82 is a region which is provided below the buffer region 20 in the diode portion 80 and which is of the same conductivity type as that of the drift region 18. A boundary between the collector region 22 and the cathode region 82 is a boundary between the transistor portion 70 and the diode portion 80.

The collector electrode 24 is provided on the back surface 23 of the semiconductor substrate 10. The collector electrode 24 is formed of a conductive material such as metal, or by stacking conductive materials.

One or more gate trench portions 40 and one or more dummy trench portions 30 are provided in the front surface 21 of the semiconductor substrate 10. Each trench portion is provided to extend from the front surface 21 of the semiconductor substrate 10 to the drift region 18 in the Z axis direction. For regions provided with at least any of the emitter region 12, the base region 14, the contact region 15 the accumulation region 16, and the anode region 84, each trench portion also extends through these regions to reach the drift region 18. The configuration of the trench portion extending through the doping region is not limited to the one manufactured in the order of forming the doping region and then forming the trench portion. The configuration of the trench portion extending through the doping region includes a configuration of the doping region being formed between the trench portions after forming the trench portion.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided inside the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21 of the semiconductor substrate 10.

The gate conductive portion 44 includes, in the Z axis direction, a region opposing to the adjacent base region 14 at the side of the mesa portion 71 with the gate dielectric film 42 interposed therebetween. When a predetermined voltage is applied to the gate conductive portion 44, a channel is formed to a surface layer being at a boundary within the base region 14 and in contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are provided on the front surface 21 side of the semiconductor substrate 10. The dummy dielectric film 32 is provided to cover an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided to a front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may be provided to extend through the interlayer dielectric film 38.

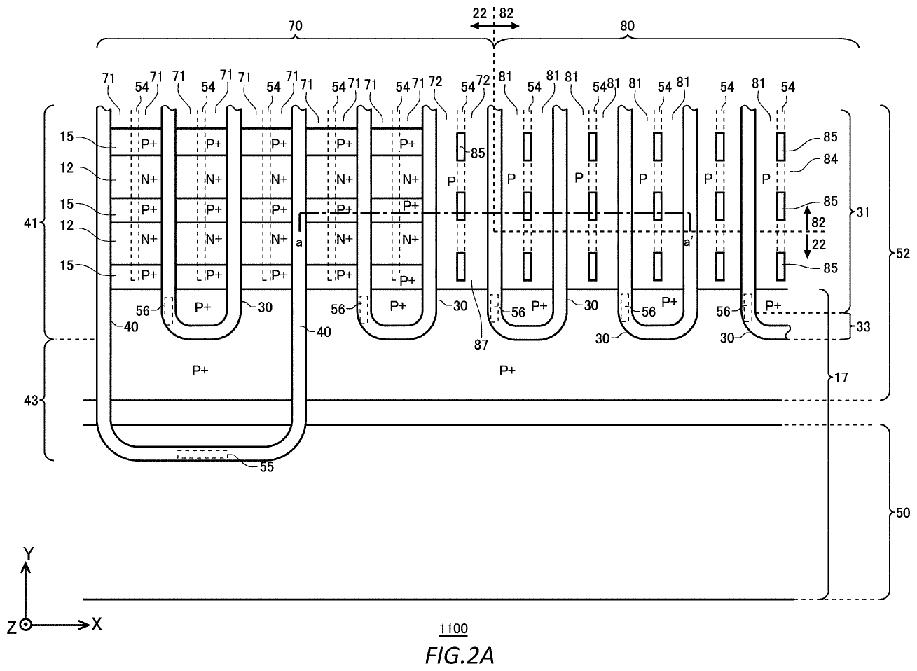

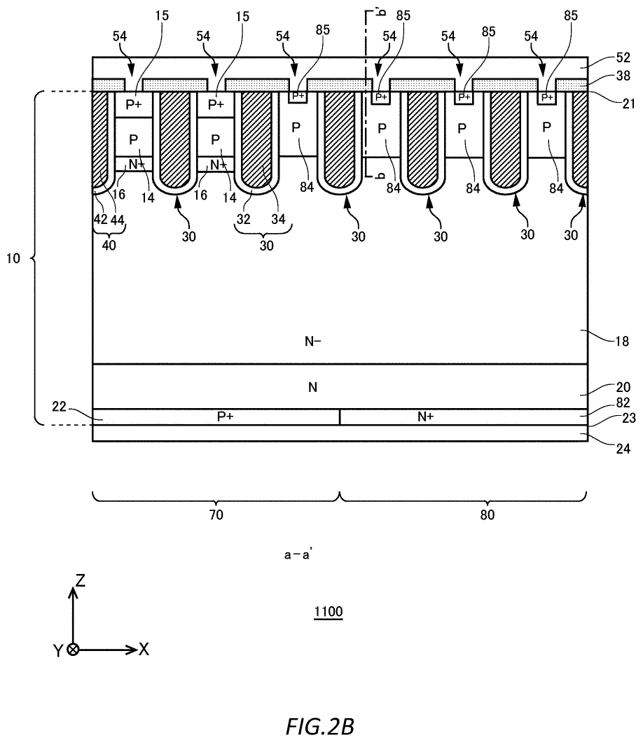

FIG. 2A shows an example of a top view of the semiconductor device 1100 according to the comparative example. FIG. 2B is a diagram showing an example of a cross section a-a′ in FIG. 2A. In the comparative example described herein, elements in common with the semiconductor device 100 according to the example are indicated by like reference numerals and descriptions of the common configurations will be omitted.

In the diode portion 80 of the semiconductor device 1100, the high concentration regions 85 are discretely provided in the Y axis direction on the front surface of the mesa portion 81, and the high concentration region 85 is surrounded by the anode region 84. That is, the semiconductor device 1100 is not provided with the low concentration region 87, and in a top view, the high concentration region 85 is surrounded by the anode region 84 exposed to the front surface of the mesa portion 81.

The semiconductor device 1100 includes the high concentration region 85 discretely provided in the Y axis direction and the anode region 84 having a lower doping concentration than that of the base region 14 in the mesa portion 81 to adjust the total amount of holes in the diode portion 80, thereby reducing the reverse recovery loss. However, as the doping concentration of the anode region 84 is lowered, the resistance of the anode region 84 is increased while the reverse recovery loss is reduced, such that the forward voltage of the diode portion 80 is increased to increase the conduction loss.

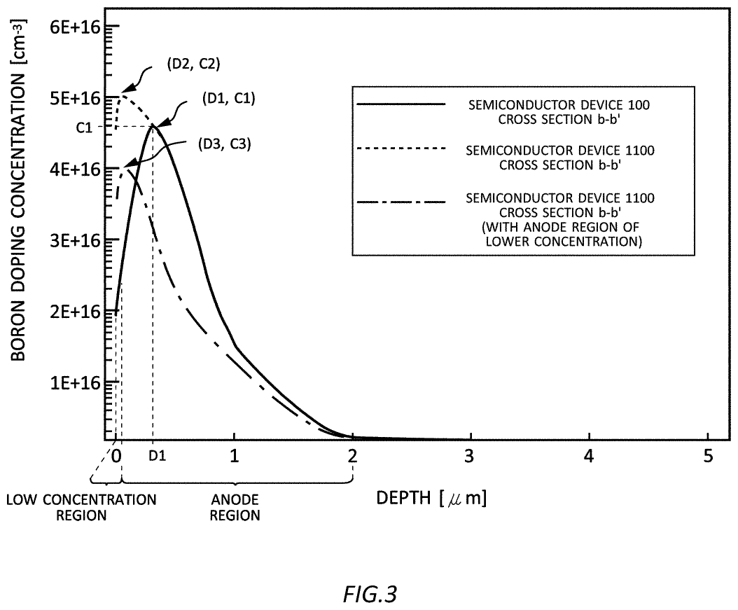

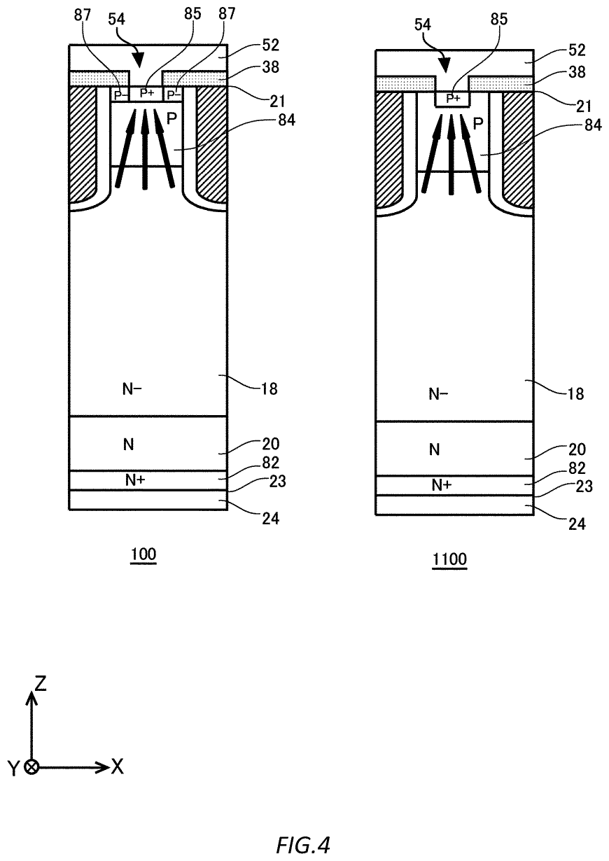

On the other hand, the semiconductor device 100 according to the example includes the low concentration region 87 on the front surface of the mesa portion 81 to suppress an increase in the forward voltage of the diode portion 80 while reducing the reverse recovery loss. Then, the principle will be described with reference to FIG. 3 and FIG. 4, by comparing the doping concentration profiles and the hole current paths in the mesa portions 81 of the semiconductor device 100 and the semiconductor device 1100.

FIG. 3 is a diagram showing the doping concentration profiles in the mesa portions 81 of the example and the comparative example. The lateral axis indicates the depth [μm] in the-Z axis direction originating from the front surface 21 of the semiconductor substrate 10, and the horizontal axis indicates the doping concentration of boron [cm⁻³] when ion implantation is performed with boron as a dopant from the front surface 21 of the semiconductor substrate 10. The solid lines indicate the doping concentration in the cross section b-b′ of the semiconductor device 100 according to the example shown in FIG. 1B, and the dashed lines and the chain lines indicate the doping concentration in the cross section b-b′ of the semiconductor device 1100 according to the comparative example shown in FIG. 2B.

First, the doping concentration profile of the semiconductor device 1100 according to the comparative example, indicated by the dashed lines, will be described. The cross section b-b′ in FIG. 2B is an X-Z plane passing through the anode region 84 and the drift region 18, in the order from the front surface 21 of the semiconductor substrate 10. A peak of the doping concentration is a peak doping concentration C2 of the anode region 84. A range from the front surface 21 of the semiconductor substrate 10 to a depth at which the doping concentration decreases to approximately zero corresponds to the anode region 84 of the P type, and a range deeper than the foregoing range corresponds to the drift region 18 of the N-type. The depth D2 of the peak doping concentration C2 of the anode region 84 of the semiconductor device 1100 is equal to or smaller than 0.3 μm.

Then, the doping concentration profile of the semiconductor device 100 according to the example, indicated by the solid lines, will be described. The cross section b-b′ in FIG. 1B is an X-Z plane passing through the low concentration region 87, the anode region 84 and the drift region 18, in the order from the front surface 21 of the semiconductor substrate 10. A peak of the doping concentration is a peak doping concentration C1 of the anode region 84.

The low concentration region 87 is a range within which the doping concentration is equal to or greater than 10% and equal to or smaller than 50% of the peak doping concentration C1 of the anode region 84. In addition, the low concentration region 87 is positioned in a range shallower than the depth D1 of the peak doping concentration C1 of the anode region 84 in the Z axis direction. In FIG. 3, the range from the front surface 21 of the semiconductor substrate 10 to the depth D1 corresponds to the low concentration region 87 of the P-type, the range from the depth D1 to a depth at which the doping concentration decreases to approximately zero corresponds to the anode region 84 of the P type, and the range deeper than the foregoing range corresponds to the drift region 18 of the N-type.

Note that, while the doping concentration profile of the high concentration region 85 is not shown in FIG. 3, the lower end of the low concentration region 87 and the lower end of the high concentration region 85 of the present example are at the same depth so that the depth D1 of the peak doping concentration C1 of the anode region 84 is in a range deeper than that of the high concentration region 85.

The low concentration region 87 of the present example is formed by, subsequent to ion implantation of boron from the front surface 21 of the semiconductor substrate 10 to form the anode region 84, depositing an oxide film on the front surface 21 of the semiconductor substrate 10 and drawing boron in the vicinity of the front surface 21 of the semiconductor substrate 10 by the oxide film. Boron is reduced in the vicinity of the front surface 21 of the semiconductor substrate 10 such that the peak doping concentration C1 of the anode region 84 is lower than the peak doping concentration C2 of the anode region 84 of the semiconductor device 1100 and the depth D1 of the peak doping concentration C1 is deeper than the depth D2 of the peak doping concentration C2 of the anode region 84 of the semiconductor device 1100.

The depth D1 of the peak doping concentration C1 of the anode region 84 of the semiconductor device 100 is equal to or greater than 0.3 μm and equal to or smaller than 0.8 μm, and preferably 0.4 μm to 0.6 μm, for example 0.5 μm. The peak doping concentration C1 of the anode region 84 is equal to or greater than 4E16 cm⁻³ and equal to or smaller than 1E17 cm⁻³. In addition, the doping concentration of the low concentration region 87 on the front surface 21 of the semiconductor substrate 10 is equal to or greater than 1E15 cm⁻³ and equal to or smaller than 3E16 cm⁻³.

Next, the doping concentration profile of the semiconductor device 1100 according to the comparative example, indicated by the chain lines, will be described. The anode region 84 is formed by ion implantation of boron a dose amount of which is smaller than that of the semiconductor device 1100 of the doping concentration profile indicated by the dashed lines.

Therefore, the peak doping concentration C3 of the doping concentration profile indicated by the chain lines is lower than the peak doping concentration C2 of the doping concentration profile indicated by the dashed lines. Note that the depth D3 of the peak doping concentration C3 is approximately the same as the depth D2 of the peak doping concentration C2.

FIG. 4 is a diagram schematically showing paths of hole currents while the diode portions 80 of the example and the comparative example are brought into conduction. FIG. 4 is schematic X-Z planes of the mesa portion 81 of the semiconductor device 100 according to the example and the mesa portion 81 of the semiconductor device 1100 according to the comparative example. The black arrows schematically illustrate the paths of hole currents when the diode portion 80 is brought into conduction.

The hole currents flow into the high concentration region 85 through the anode region 84. If the doping concentration of the anode region 84 is low at this time, the resistance of the anode region 84 is so large that a flow of hole currents is suppressed. Therefore, the forward voltage of the diode portion 80 is increased to increase the conduction loss. That is, referring to FIG. 3 again, in the semiconductor device 1100 according to the comparative example indicated by the chain lines, the doping concentration of the anode region 84 is lower and the total amount of holes is smaller than in the semiconductor device 1100 according to the comparative example indicated by the dashed lines, so that the forward voltage of the diode portion 80 is increased while the reverse recovery loss is reduced.

On the other hand, in the semiconductor device 100 according to the example, the low concentration region 87 is provided to surround the high concentration region 85 on the front surface of the mesa portion 81, while the anode region 84 is provided below the high concentration region 85, which is in common with the structure of the semiconductor device 1100 according to the comparative example. As indicated by the black arrows in FIG. 4, the hole currents flow to the lower end of the high concentration region 85 through the anode region 84, but not through the lateral sides of the high concentration region 85, that is, the low concentration region 87 of the semiconductor device 100. Therefore, if the doping concentration of the anode region 84 of the semiconductor device 100 according to the example is the same as the doping concentration of the anode region 84 of the semiconductor device 1100 according to the comparative example, the forward voltages of the diode portions 80 are almost the same.

In this manner, the semiconductor device 100 according to the example includes the low concentration region 87 on the front surface of the mesa portion 81 having a doping concentration lower than that of the anode region 84 so that the reverse recovery loss can be reduced. On the other hand, the semiconductor device 100 according to the example includes the anode region 84 below the high concentration region 85 having a doping concentration higher than that of the low concentration region 87 so that an increase in the resistance can be suppressed and an increase in the forward voltage of the diode portion 80 can be suppressed.

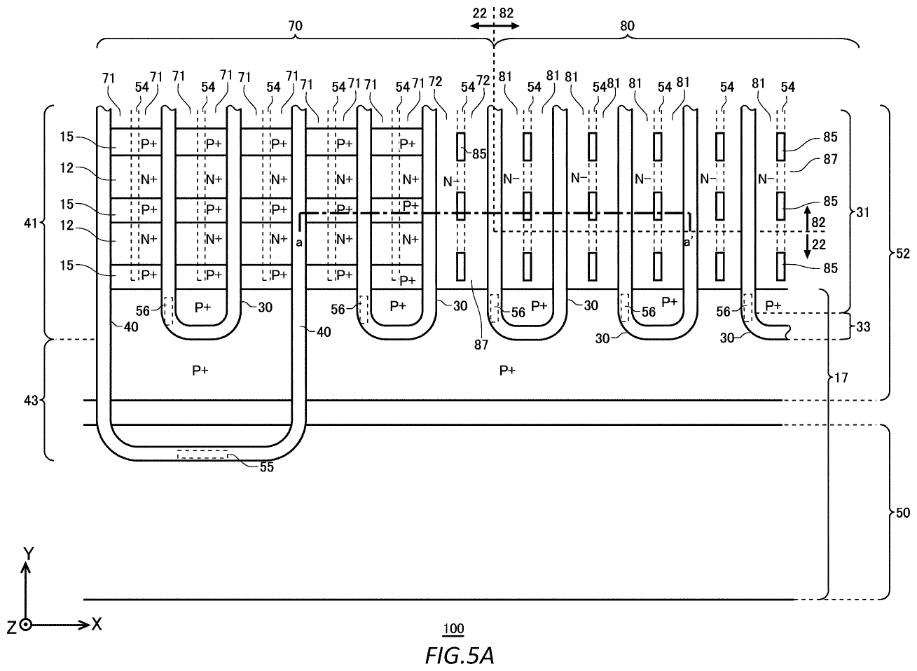

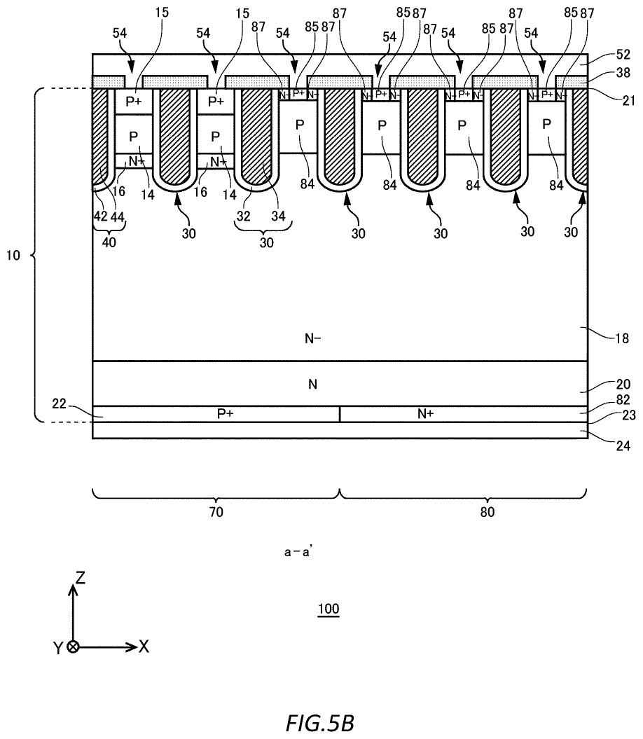

FIG. 5A shows another example of a top view of the semiconductor device 100. FIG. 5B is a diagram showing an example of a cross section a-a′ in FIG. 5A. The present example is different from the example of FIG. 1A and FIG. 1B in the low concentration region 87 being a region of a different conductivity type from the anode region 84.

The low concentration region 87 of the present example is, for example, of the N-type. The low concentration region 87 of the present example may be formed by ion implantation of dopants such as boron from the front surface 21 of the semiconductor substrate 10 to form the anode region 84, followed by ion implantation of dopants such as arsenic (As). In this manner, the low concentration region 87 of the N-type is provided such that hole injection can be suppressed to suppress the reverse recovery loss, thereby achieving the effect similar to that of the example of FIG. 1A and FIG. 1B.

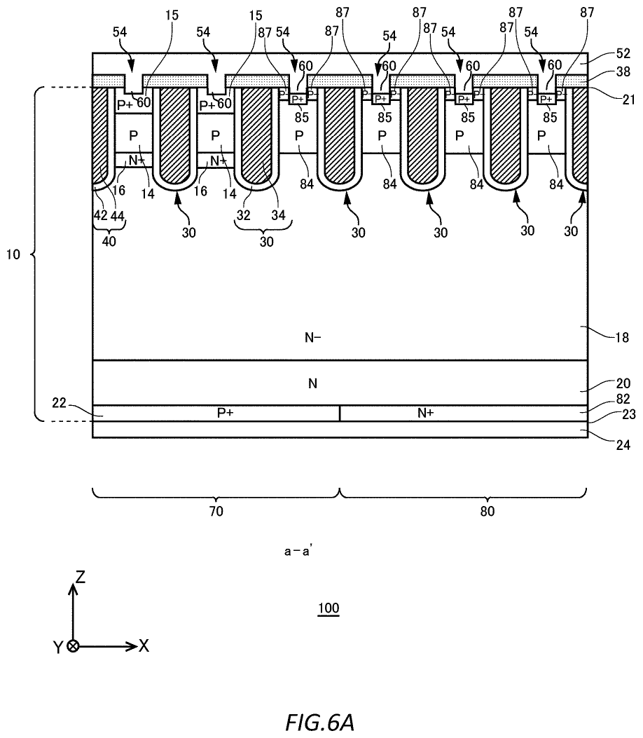

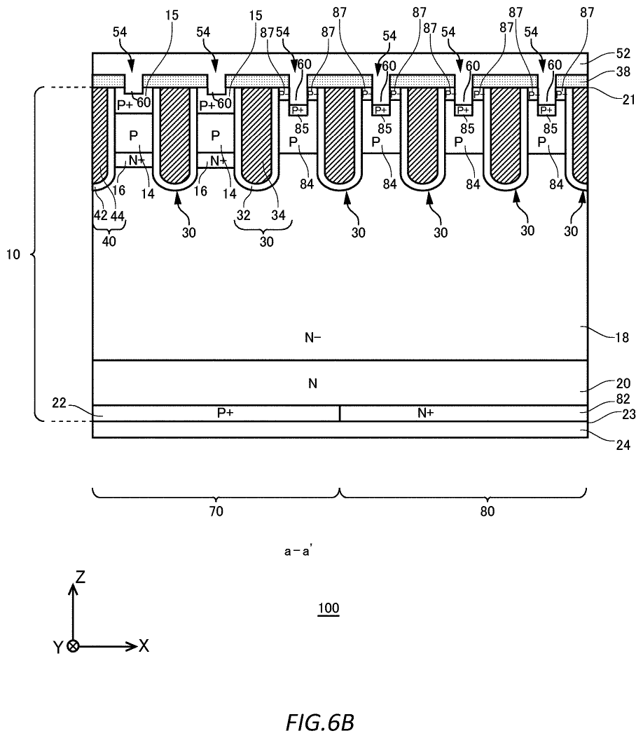

FIG. 6A is a diagram showing another example of a cross section a-a′ in FIG. 1A. The example of FIG. 6A is different from the example of FIG. 1A and FIG. 1B in a trench contact portion 60 provided below the contact hole 54.

The trench contact portion 60 is provided on the front surface 21 of the semiconductor substrate 10. The trench contact portion 60 electrically connects the emitter electrode 52 and the semiconductor substrate. The trench contact portion 60 is provided continuously from the contact hole 54. The trench contact portion 60 of the present example is provided to extend in the Y axis direction in each of the mesa portion 71 and the mesa portion 81.

The trench contact portion 60 contains a conductive material filled in the contact hole 54. A barrier metal formed of titanium, titanium compound or the like may be provided inside the trench contact portion 60 and the contact hole 54. Further, in the trench contact portion 60 and the contact hole 54, a plug formed of tungsten or the like may be provided via the barrier metal.

The trench contact portion 60 is provided to facilitate withdrawal of the minority carrier (holes, for example). This can improve the breakdown withstand capability such as a latch up withstand capability due to minority carriers.

For example, the trench contact portion 60 is formed by etching the interlayer dielectric film 38. The trench contact portion 60 has a lower end having a substantially planar shape. The trench contact portion 60 may have a tapered form with an inclined side wall. Alternatively, the side wall of the trench contact portion 60 may also be provided to be substantially perpendicular to the front surface 21 of the semiconductor substrate 10.

The lower end of the trench contact portion 60 of the present example is deeper than the lower end of the low concentration region 87 in the Z axis direction. The low concentration region 87 of the present example is provided on the side wall of the trench contact portion 60. The low concentration region 87 may also be provided at the lower end of the trench contact portion 60.

The high concentration regions 85 of the present example are discretely provided at the lower end of the trench contact portion 60. This can reduce the contact resistance to facilitate withdrawal of holes, thereby improving the breakdown withstand capability such as the latch up withstand capability.

The high concentration region 85 may also diffuse from the lower end of the trench contact portion 60 to cover at least a part of the side wall of the trench contact portion 60. The lower end of the high concentration region 85 may be the same depth as or may be deeper than the lower end of the low concentration region 87.

FIG. 6B is a diagram showing another example of a cross section a-a′ in FIG. 1A. The example of FIG. 6B is different from the example of FIG. 6A in the lower end of the trench contact portion 60 being shallower than the lower end of the low concentration region 87 in the Z axis direction.

The low concentration region 87 of the present example is provided on the side wall of the trench contact portion 60. The high concentration regions 85 of the present example are discretely provided at the lower end of the trench contact portion 60. Similarly to the example of FIG. 6A, this can reduce the contact resistance to facilitate withdrawal of holes, thereby improving the breakdown withstand capability such as the latch up withstand capability.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such alterations or improvements are made can be included in the technical scope of the present invention.

It should be noted that the operations, procedures, steps, stages, and the like of each processing performed by an apparatus, system, program, and method shown in the claims, specification, or drawings can be realized in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 20: buffer region, 21: front surface, 22: collector region, 23: back surface, 24: collector electrode, 30: dummy trench portion, 31: extending portion, 33: connecting portion, 32: dummy dielectric film, 34: dummy conductive portion, 38: interlayer dielectric film, 40: gate trench portion, 41: extending portion, 43: connecting portion, 42: gate dielectric film, 44: gate conductive portion, 50: gate metal layer, 52: emitter electrode, 54: contact hole, 55: contact hole, 56: contact hole, 60: trench contact portion, 70: transistor portion, 71: mesa portion, 72: boundary region, 80: diode portion, 81: mesa portion, 82: cathode region, 84: anode region, 85: high concentration region, 87: low concentration region, 100: semiconductor device, 1100: semiconductor device

What is claimed is:

1. A semiconductor device comprising a transistor portion and a diode portion, wherein the semiconductor device including:
a plurality of trench portions provided on a front surface of a semiconductor substrate;
a drift region of a first conductivity type provided in the semiconductor substrate;
an anode region of a second conductivity type provided above the drift region in the diode portion;
a low concentration region provided above the anode region and having a doping concentration an absolute value of which is lower than that of the anode region; and
a high concentration region of the second conductivity type provided above the anode region and having a doping concentration higher than that of the anode region.

2. The semiconductor device according to claim 1, wherein
the doping concentration of the low concentration region is equal to or greater than 10% and equal to or smaller than 50% of a peak of the doping concentration of the anode region.

3. The semiconductor device according to claim 1, wherein
the doping concentration of the low concentration region on the front surface of the semiconductor substrate is equal to or greater than 1E15 cm⁻³ and equal to or smaller than 3E16 cm⁻³.

4. The semiconductor device according to claim 1 wherein
in a top view, the low concentration region is provided to surround the high concentration region on the front surface of the semiconductor substrate.

5. The semiconductor device according to claim 1, wherein
in a depth direction of the semiconductor substrate, the low concentration region is shallower than than a peak position of a doping concentration of the anode region.

6. The semiconductor device according to claim 1, wherein
the low concentration region is of a first conductivity type.

7. The semiconductor device according to claim 1, wherein
a peak of a doping concentration of the anode region is equal to or greater than 4E16 cm⁻³ and equal to or smaller than 1E17 cm⁻³.

8. The semiconductor device according to claim 7, wherein
in a depth direction of the semiconductor substrate, a peak position of a doping concentration of the anode region is positioned equal to or greater than 0.3 μm and equal to or smaller than 0.8 μm from the front surface of the semiconductor substrate.

9. The semiconductor device according to claim 1, wherein
in a depth direction of the semiconductor substrate, a peak position of a doping concentration of the anode region is deeper than the high concentration region.

10. The semiconductor device according to claim 1, wherein
a thickness of the anode region in a depth direction of the semiconductor substrate is equal to or greater than 0.5 μm and equal to or smaller than 1.0 μm.

11. The semiconductor device according to claim 1, wherein
a doping concentration of the high concentration region is equal to or greater than 2E19 cm⁻³ and equal to or smaller than 2E20 cm⁻³.

12. The semiconductor device according to claim 1, wherein
a thickness of the high concentration region in a depth direction of the semiconductor substrate is equal to or greater than 0.1 μm and equal to or smaller than 1.0 μm.

13. The semiconductor device according to claim 1, wherein
a doping concentration of the high concentration region is equal to or greater than 200 times and equal to or smaller than 2000 times a doping concentration of the anode region.

14. The semiconductor device according to claim 1, wherein
the high concentration region is discretely provided in a trench extending direction.

15. The semiconductor device according to claim 1, wherein
the high concentration region is provided to be spaced apart from the plurality of trench portions.

16. The semiconductor device according to claim 1, comprising
a cathode region of a first conductivity type below the low concentration region and the high concentration region, having a doping concentration higher than that of the drift region.

17. The semiconductor device according to claim 1, comprising
a trench contact portion provided on the front surface of the semiconductor substrate.

18. The semiconductor device according to claim 17, wherein
the high concentration region is provided at a lower end of the trench contact portion.

19. The semiconductor device according to claim 17, wherein
the low concentration region is provided at a lower end and a side wall of the trench contact portion.

20. The semiconductor device according to claim 19, wherein
in a depth direction of the semiconductor substrate, a lower end of the trench contact portion is shallower than a lower end of the low concentration region.

21. The semiconductor device according to claim 17, wherein
in a depth direction of the semiconductor substrate, a lower end of the trench contact portion is deeper than a lower end of the low concentration region.
